(19) United States
(12) Patent Application Publication
(10) Pub. No.: US 2009/0027093 A1
(43) Pub. Date: Jan. 29, 2009

(54) SAMPLING CIRCUIT AND METHOD

(76) Inventors: Yi-Lin Chen, Taipei City (TW); Tung-Chen Kuo, Hsin-Chu City (TW); Yi-Chih Huang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 12/031,709

(22) Filed: Feb. 15, 2008

(30) Foreign Application Priority Data
Feb. 15, 2007 (TW) 096105825

(51) Int. Cl. H03L 7/06; G11C 7/06

(52) U.S. Cl. 327/158; 365/189.07

(57) ABSTRACT

A sampling circuit for sampling an input data to obtain an output data includes a delay control unit, a first sampling unit, a second sampling unit, and a processing unit. The delay control unit delays a sampling signal for a first delay time to generate a first delayed signal, and delays the sampling signal for a second delay time to generate a second delayed signal; the first sampling unit samples the input data to obtain a first sampled value according to the first delayed signal, wherein the first sampling unit is utilized to generate the output data; the second sampling unit samples the input data to obtain a second sampled value according to the second delayed signal; and the processing unit controls the delay control unit to adjust at least the first delay time according to the first and second sampled values to calibrate the first delayed signal.

### BACKGROUND OF THE INVENTION

1. Field of the Invention

The present invention relates to data sampling technology, and more particularly, to a sampling circuit and a sampling method thereof for sampling data correctly by comparing read-back data to dynamically calibrate a sampling signal (commonly a clock).

2. Description of the Prior Art

In general, a sampling signal (commonly a clock) is provided in digital circuits as a reference for sampling data. For example, data signals and data sampling signals exist in a double data rate random access memory (DDR DRAM), wherein rising edges and falling edges of the data sampling signal are required to be within a data valid sections of the data signals in an ideal condition so that a system can sample bit values of input data correctly.

In a conventional system, the sampling circuit will first enter a test mode when the system starts to perform operations. The sampling circuit will detect whether the data sampling signals are able to sample the data signals correctly by reading a series of known bit stream data, and then determine an optimal data sampling signal. When the operation time increases in the circuit, however, various environment factors (such as temperature) will change accordingly, and these changes will cause the phase relation between the data sampling signals and the data signals to have variations so that the bit values of the sampled data signals have a high possibility of being incorrect. Prior art methods either choose to ignore this problem or enter the test mode again after the system is operational for a certain time period, then read the known bit stream data in order to perform the calibration operation. If the bit stream is too short, it is not possible to represent a valid long-term trend statistically since it may be interfered with by noise; if the bit stream is too long or the test frequency is too high, then the bandwidth of the system will be wasted, thereby affecting operations in the normal operation mode.

### SUMMARY OF THE INVENTION

It is therefore one of the objectives of the present invention to provide a sampling circuit and a sampling method thereof for sampling data correctly by comparing read-back data to dynamically calibrate a sampling signal (which is commonly a clock), and in this way, the present invention does not need to interrupt the operations that the system is performing or enter a test mode to calibrate the sampling signal, so as to solve the above problem.

According to an embodiment of the present invention, a sampling circuit is disclosed. The sampling circuit includes: a delay control unit, for delaying a sampling signal for a first delay time to generate a first delayed signal, and delaying the sampling signal for a second delay time to generate a second delayed signal; a first sampling unit, coupled to the delay control unit, for sampling the input data to obtain a first sampled value according to the first delayed signal, wherein the first sampling unit is utilized to generate the output data; a second sampling unit, coupled to the delay control unit, for sampling the input data to obtain a second sampled value according to the second delayed signal; and a processing unit, coupled to the delay control unit, the first and second sampling units, for controlling the delay control unit to adjust at least the first delay time according to the first and second sampled values to calibrate the first delayed signal.

According to an embodiment of the present invention, a sampling method is further disclosed. The sampling method includes: delaying a sampling signal for a first delay time to generate a first delayed signal; delaying the sampling signal for a second delay time to generate a second delayed signal; sampling the input data to obtain a first sampled value according to the first delayed signal; sampling the input data to obtain a second sampled value according to the second delayed signal; and adjusting at least the first delay time according to the first and second sampled values to calibrate the first delayed signal.

According to an embodiment of the present invention, a sampling method for a memory is yet further disclosed. The sampling method includes: generating a data signal; generating a data sampling signal; delaying the data sampling signal by a first delay time to generate a first delayed signal; delaying the data sampling signal by a second delay time to generate a second delayed signal; utilizing the first delayed signal to sample the data signal so as to generate a first sampled value; utilizing the second delayed signal to sample the data signal so as to generate a second sampled value; performing a first comparing operation on the first sampled value and the second sampled value; and adjusting at least the first delay time according to a result of the first comparing operation.

These and other objectives of the present invention will no doubt become obvious to those of ordinary skill in the art after reading the following detailed description of the embodiment that is illustrated in the various figures and drawings.

### BRIEF DESCRIPTION OF THE DRAWINGS

FIG. 1 shows a simplified block diagram of a sampling circuit according to an embodiment of the present invention.

FIG. 2 is a diagram showing waveforms of the input data Dᵢₙ, the first delayed signal S_{D1}, a second delayed signal S_{D2}, and a third delayed signal S_{D3} and relations between the first sampled value Dₒᵤₜ, a second sampled value D₂, and a third sampled value D₃.

FIG. 3 is a diagram showing waveforms of the input data Dᵢₙ, the first delayed signal S_{D1} and the third delayed signal S_{D3} and relations between the first sampled value Dₒᵤₜ and the third sampled value D₃.

### DETAILED DESCRIPTION

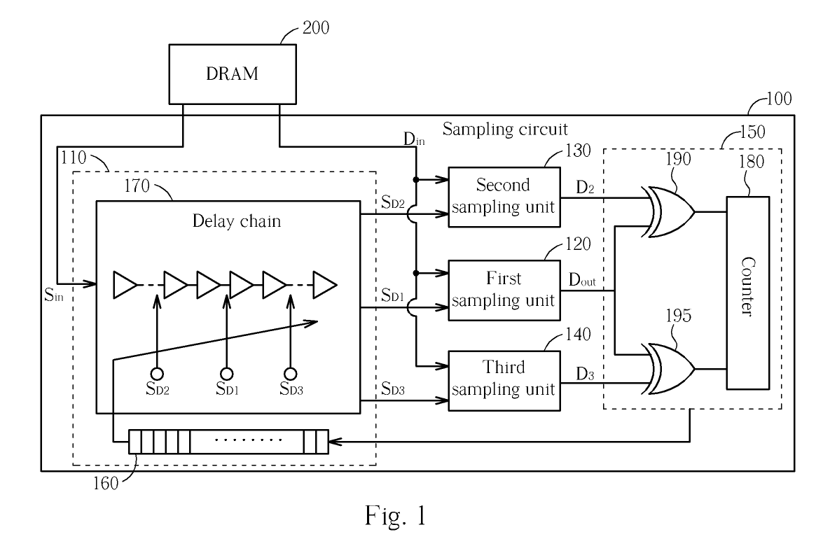

Please refer to FIG. 1. FIG. 1 shows a simplified block diagram of a sampling circuit 100 according to an embodiment of the present invention. In this embodiment, the sampling circuit 100 is a data sampling circuit of a dynamic random access memory (DRAM), which receives a data signal Dᵢₙ and a data sampling signal Sᵢₙ from a DRAM 200, and performs a sampling operation according to the data signal Dᵢₙ and the data sampling signal Sᵢₙ. However, a person skilled in the pertinent art should be able to easily understand that the sampling circuit of the present invention is not limited in the memory field. The sampling circuit 100 includes a delay control unit 110, a first sampling unit 120, a second sampling unit 130, a third sampling unit 140, and a processing unit 150. In this embodiment, when the sampling circuit 100 performs an initialization operation, the sampling circuit 100 initially enters a test mode. At this moment, a series of known bit stream data are inputted to the sampling circuit 100 as an input data Dᵢₙ and after the delay control unit 110 delays a sampling signal Sᵢₙ for a plurality of delay times the sampling units respectively sample the bit stream to obtain a plurality of sampled values corresponding to the plurality of delay times. The processing unit 150 determines an initial delay time according to a comparing result after comparing the known bit stream with the plurality of sampled values, so as to sample the bit stream correctly and have a maximum error margin after the sampling signal Sᵢₙ is delayed for the initial delay time. Please note that the test mode operation during the initialization operation is not meant to limit the scope of the present invention.

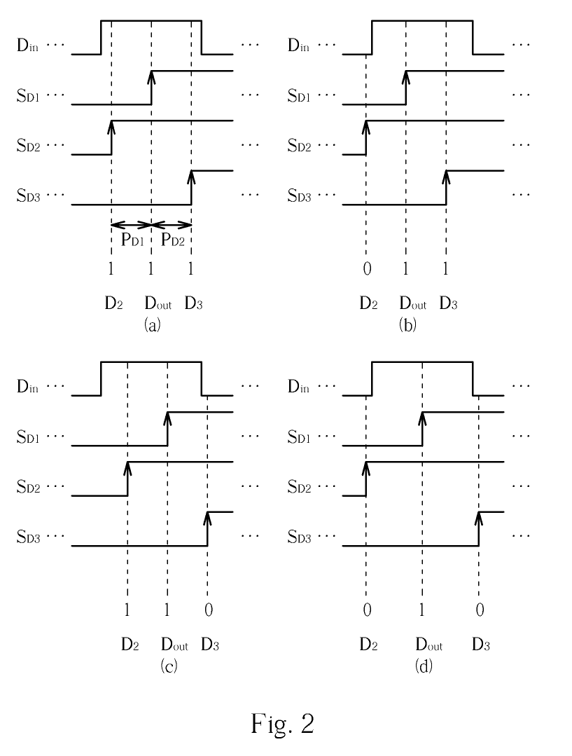

After the initial delay time is determined, the sampling circuit 100 returns to a normal operation mode. At this moment, the input data Dᵢₙ is inputted to the sampling circuit 100, and the delay control unit 110 uses the initial delay time as a first delay time for delaying the sampling signal Sᵢₙ to generate a first delayed signal S_{D1} and input the first delayed signal S_{D1} to the first sampling unit 120. The first sampling unit 120 uses the first delayed signal S_{D1} to sample the input data Dᵢₙ so as to generate a first sampled value Dₒᵤₜ as an output data. Please refer to FIG. 1 and FIG. 2 together. FIG. 2 is a diagram showing waveforms of the input data Dᵢₙ, the first delayed signal S_{D1}, a second delayed signal S_{D2}, and a third delayed signal S_{D3} and relations between the first sampled value Dₒᵤₜ, a second sampled value D₂, and a third sampled value D₃. The delay control unit 110 also generates a second delay time less than the first delay time and a third delay time greater than the first delay time. The sampling signal Sᵢₙ becomes the second delayed signal S_{D2} after being delayed for the second delay time, and the second delayed signal S_{D2} is inputted to the second sampling unit 130. The second sampling unit 130 uses the second delayed signal S_{D2} to sample the input data Dᵢₙ so as to generate a second sampled value D₂. Similarly, the sampling signal Sᵢₙ becomes the third delayed signal S_{D3} after being delayed for the third delay time, and the third delayed signal S_{D3} is inputted to the third sampling unit 140. The third sampling unit 140 uses the third delayed signal S_{D3} to sample the input data Dᵢₙ so as to generate a third sampled value D₃. Taking a bit value of the input signal as 1 and sampling the input signal according to rising edge triggers as an example, please refer to FIG. 2 (a). Since the first delayed signal S_{D1} is generated by using the initial delay time for delaying the sampling signal Sᵢₙ, the rising edge of the first delayed signal S_{D1} theoretically occurs in center points of data valid sections of the bit value being 1. In this way, the maximum error margin is obtained. In this embodiment, a first difference P_{D1} between the first delay time and the second delay time is equal to a second difference P_{D2} between the first delay time and the third delay time, and the first sampled value Dₒᵤₜ, the second sampled value D₂, and the third sampled value D₃ that are sampled according to the first delayed signal S_{D1}, the second delayed signal S_{D2}, and the third delayed signal S_{D3} all have a bit value of 1. Please note that the first difference P_{D1} and the second difference P_{D2} can be determined by a designer according to the allowable error margin of the sampling circuit 100.

When the operation time increases and various environment factors (such as temperature) change accordingly, the phase relation between the input data Dᵢₙ and the first delayed signal S_{D1} has a variance and which possibly causes the rising edge of the first delayed signal S_{D1} to move forward or backward. In a first case, if the moving forward value of the rising edge of the first delayed signal S_{D1} is greater than a threshold value, as shown in FIG. 2 (b), then the first sampled value Dₒᵤₜ sampled according to the first delayed signal S_{D1} and the third sampled value D₃ sampled according to the third delayed signal S_{D3} will still be the correct bit value of 1, but the second sampled value D₂ sampled according to the second delayed signal S_{D2} will be the wrong bit value of 0. In other words, when the sampling circuit 100 is in the normal operation mode, if the processing unit 150 detects that the first sampled value Dₒᵤₜ and the third sampled value D₃ are identical to each other and the second sampled value D₂ is different from the first sampled value Dₒᵤₜ and the third sampled value D₃, then the processing unit 150 can judge that the rising edge of the first delayed signal S_{D1} moves forward, and the processing unit 150 will send a control signal S_{C} to notify the delay control unit 110 to increase the first delay time until the first sampled value Dₒᵤₜ, the second sampled value D₂, and the third sampled value D₃ are all identical to each other. Similarly, in a second case, if the moving backward value of the rising edge of the first delayed signal S_{D1} is greater than a threshold value, as shown in FIG. 2 (c), then the first sampled value Dₒᵤₜ sampled according to the first delayed signal S_{D1} and the second sampled value D₂ sampled according to the second delayed signal S_{D2} will still be the correct bit value of 1, but the third sampled value D₃ sampled according to the third delayed signal S_{D3} will be the wrong bit value of 0. In other words, when the sampling circuit 100 is in the normal operation mode, if the processing unit 150 detects that the first sampled value Dₒᵤₜ and the second sampled value D₂ are identical to each other and the third sampled value D₃ is different from the first sampled value Dₒᵤₜ and the second sampled value D₃, then the processing unit 150 can judge that the rising edge of the first delayed signal S_{D1} moves backward, and the processing unit 150 will send the control signal S_{C} to notify the delay control unit 110 to decrease the first delay time until the first sampled value Dₒᵤₜ, the second sampled value D₂, and the third sampled value D₃ are all identical to each other. Please note that knowing the correct bit value of the input data Dᵢₙ is not necessary for the present invention, and the input data Dᵢₙ can be the data read by the system in the normal operation mode. In other words, utilizing the sampling circuit of the present invention does not require interrupting the operations that the system is performing and enables performing the calibration on the fly. Therefore, the problem of occupying the system bandwidth does not need to be considered.

The processing unit 150 may also detect that both the second sampled value D₂ and the third sampled value D₃ are different from the first sampled value Dₒᵤₜ, as shown in FIG. 2 (d). This case will occur when the values of the first difference P_{D1} and the second difference P_{D2} defined by the designer are too large, causing both the second delayed signal S_{D2} and the third delayed signal S_{D3} to sample the wrong bit values. Thus, when the processing unit 150 detects that both the second sampled value D₂ and the third sampled value D₃ are different from the first sampled value Dₒᵤₜ, the processing unit 150 will send the control signal S_{C} to notify the delay control unit 110 to increase the second delay time and decrease the third delay time so as to decrease the first difference P_{D1} and the second difference P_{D2} until one of the second sampled value D₂ and the third sampled value D₃ is identical to the first sampled value Dₒᵤₜ.

In this embodiment, the delay control unit 110 includes a delay chain 170 that is formed by a plurality of delay units (64, for example) connecting with each other in series. In addition, the delay control unit 110 also includes a shift register 160 having a number of fields, wherein the number of the fields is equal to the number of the delay units, and only a value of one of the fields is set to be 1 and the others are set to be 0 so as to label a delay unit with a stage number from which the first delayed signal SD1 should be taken out. In this embodiment, there is a fixed difference of stage number between the stage number of the delay unit from which the second delayed signal SD2 is taken out and the stage number of the delay unit from which the first delayed signal SD1 is taken out, and there is also a fixed difference of stage number between the stage number of the delay unit from which the third delayed signal SD3 is taken out and the stage number of the delay unit from which the first delayed signal SD1 is taken out (as shown in FIG. 2, the fixed stage number differences are both 2 stages). Thus, when the stage number of the delay unit from which the first delayed signal SD1 is taken out changes in accordance with a variation of the values stored in the shift register 160, the stage number of the delay unit from which the second delayed signal SD2 is taken out and the stage number of the delay unit from which the third delayed signal SD3 is taken out will also change accordingly. Please note that, although the shift register 160 is utilized to realize the labeling of the delay time of the delayed signals, this is only for illustrative purposes and is not meant to be a limitation of the present invention. In addition, although the delay time differences between the second delayed signal SD2 and the first delayed signal SD1 and between the third delayed signal SD3 and the first delayed signal SD1 are fixed values in this embodiment, this is only for illustrative purposes and is not meant to be a limitation of the present invention. In the other embodiments, the delay time differences are not required to be the fixed values, and can be other arbitrary values in accordance with the control of the processing unit.

In this embodiment, the processing unit 150 includes a first comparing unit 190 and a second comparing unit 195 that are both realized by a XOR gate, wherein the first comparing unit 190 is utilized for comparing the first sampled value Dout with the second sampled value D2, and the second comparing unit 195 is utilized for comparing the first sampled value Dout with the third sampled value D3. In order to improve the stability of the sampling circuit 100, the processing unit 150 can further include a counter 180, which is utilized for counting a disparity value when the first comparing unit 190 and the second comparing unit 195 respectively detect that one of the first, second, and third sampled values is different from the other two sampled values, and when the disparity value is greater than a threshold value, the processing unit 150 will indicate the delay control unit 110 to increase (in a case of the second sampled value D2 being different from the first sampled value Dout and the third sampled value D3) or decrease (in a case of the third sampled value D3 being different from the first sampled value Dout and the second sampled value D2) the first delay time or decrease the first and second differences (in a case of the second sampled value D2 and the third sampled value D3 being different from the first sampled value Dout). The above scheme is for observing the variations of the sampled values, so as to prevent the processing unit 150 from indicating the delay control unit 110 to adjust the first delay time, the second delay time, and the third delay time erroneously.

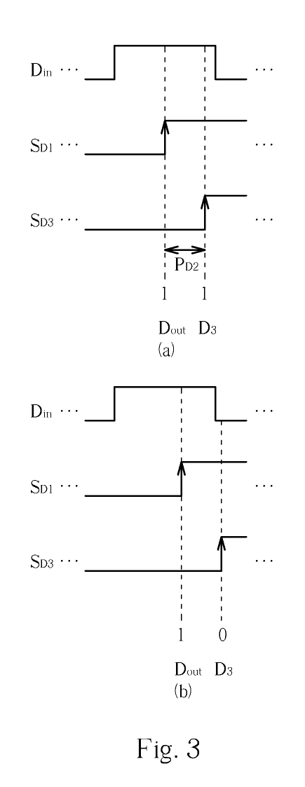

Please note that FIG. 1 shows an embodiment of the present invention. Since the effect of the environment factors for the shifting of the first delayed signal SD1 is a fixed trend in general, it is possible to determine whether to adjust the delay time by detecting two sampled values only. In other words, it is practical to retain only one of the second sampling unit 130 and the third sampling unit 140. For example, in a case where the rising edge of the first delayed signal SD1 is only able to move backward but never moves forward, the second sampling unit 130 can be abandoned; otherwise, in a case that the rising edge of the first delayed signal SD1 is only able to move forward but never moves backward, the third sampling unit 140 can be abandoned. Please refer to FIG. 3, which shows the case where the rising edge of the first delayed signal SD1 is only able to move backward but never moves forward. FIG. 3 is a diagram showing waveforms of the input data Din, the first delayed signal SD1 and the third delayed signal SD3 and relations between the first sampled value Dout and the third sampled value D3. Presuming that the second difference PD2 is determined properly in the initial state, then the first delayed signal SD1 and the third delayed signal SD3 both sample the input data Din correctly in the normal operation mode in general as shown in FIG. 3 (a), and thus the first sampled value Dout and the third sampled value D3 are both the correct bit values of 1. Since the rising edge of the first delayed signal SD1 is only able to move backward, the second sampled value D2 does not need to be considered as shown in FIG. 2. The only condition occurring is shown in FIG. 3 (5). Since the rising edge of the first delayed signal SD1 is only able to move backward, when the processing unit 150 detects that the first sampled value Dout is different from the third sampled value D3, the processing unit 150 will send a control signal SC to notify the delay control unit 110 to decrease the first delay time until the first sampled value Dout and the third sampled value D3 are identical to each other. Similarly, if the rising edge of the first delayed signal SD1 is only able to move forward but never moves backward then the third sampling unit 140 can be abandoned. Further explanation of the details and operations are omitted herein for the sake of brevity.

Those skilled in the art will readily observe that numerous modifications and alterations of the device and method may be made while retaining the teachings of the invention.

What is claimed is:

1. A sampling circuit for sampling an input data to obtain an output data, the sampling circuit comprising:
a delay control unit, for delaying a sampling signal for a first delay time to generate a first delayed signal, and delaying the sampling signal for a second delay time to generate a second delayed signal;
a first sampling unit, for sampling the input data to obtain a first sampled value according to the first delayed signal, wherein the first sampling unit is utilized to generate the output data;
a second sampling unit, for sampling the input data to obtain a second sampled value according to the second delayed signal; and
a processing unit, for controlling the delay control unit to adjust at least the first delay time according to the first and second sampled values to calibrate the first delayed signal.

2. The sampling circuit of claim 1, wherein when the sampling unit enters a test mode, the delay control unit sets the first delay time according to a test result and determines the second delay time after the first delay time is set; and the sampling circuit samples the input data to obtain the output data in a normal operation mode.

3. The sampling circuit of claim 1, wherein if the processing unit detects that the first and second sampled values are different from each other, then the processing unit simultaneously adjusts the first delay time and the second delay time until the first and second sampled values are identical to each other.

4. The sampling circuit of claim 3, wherein the processing unit comprises a counter for counting a disparity value when the processing unit detects that the first and second sampled values are different from each other, and when the disparity value is greater than a threshold value, the processing unit simultaneously adjusts the first delay time and the second delay time until the first and second sampled values are identical to each other.

5. The sampling circuit of claim 1, further comprising:
a third sampling unit, coupled to the delay control unit, for sampling the input data to obtain a third sampled value according to a third delayed signal;
wherein the delay control unit delays the sampling signal for a third delay time to generate a third delayed signal, and the processing unit controls the delay control unit to adjust at least the first delay time according to the first, second, and third sampled values to calibrate the first delayed signal.

6. The sampling circuit of claim 5, wherein when the sampling unit enters a test mode, the delay control unit sets the first delay time according to a test result and then sets the second delay time to be less than the first delay time and the third delay time to be greater than the first delay time, where a first difference between the first delay time and the second delay time is equal to a second difference between the first delay time and the third delay time; and the sampling circuit samples the input data to obtain the output data in a normal operation mode.

7. The sampling circuit of claim 6, wherein if the processing unit detects that the first and second sampled values are identical to each other and the third sampled value is different from the first sampled value, then the processing unit decreases the first delay time, the second delay time, and the third delay time until the first, second, and third sampled values are all identical to each other; if the processing unit detects that the first and third sampled values are identical to each other and the second sampled value is different from the first sampled value, then the processing unit increases the first delay time, the second delay time, and the third delay time until the first, second, and third sampled values are all identical to each other; if the processing unit detects that the second and third sampled values are both different from the first sampled value, then the processing unit decreases the first and second differences until one of the second and third sampled values is identical to the first sampled value.

8. The sampling circuit of claim 7, wherein the processing unit further comprises a counter for counting a disparity value when the processing unit detects that one of the first, second, and third sampled values is different from the other two sampled values, and when the disparity value is greater than a threshold value, the processing unit adjusts the first delay time, the second delay time, and the third delay time or decreases the first and second differences.

9. The sampling circuit of claim 7, wherein the input data is a memory data.

10. A sampling method for sampling an input data to obtain an output data, the sampling method comprising:
delaying a sampling signal for a first delay time to generate a first delayed signal;
delaying the sampling signal for a second delay time to generate a second delayed signal;
sampling the input data to obtain a first sampled value according to the first delayed signal;
sampling the input data to obtain a second sampled value according to the second delayed signal; and
adjusting at least the first delay time according to the first and second sampled values to calibrate the first delayed signal.

11. The sampling method of claim 10, further comprising:
setting the first delay time according to a test result in a test mode and determining the second delay time after the first delay time is set; and
sampling the input data to obtain the output data in a normal operation mode.

12. The sampling method of claim 10, wherein if the first and second sampled values are different from each other, then adjust the first delay time and the second delay time until the first and second sampled values are identical to each other.

13. The sampling method of claim 12, further comprising:
counting a disparity value when detecting that the first and second sampled values are different from each other;
wherein when the disparity value is greater than a threshold value, simultaneously increasing or decreasing the first delay time and the second delay time until the first and second sampled values are identical to each other.

14. The sampling method of claim 10, further comprising:
delaying the sampling signal for a third delay time to generate a third delayed signal, and
sampling the input data to obtain a third sampled value according to the third delayed signal;
wherein the step of adjusting at least the first delay time adjusts at least the first delay time according to the first, second, and third sampled values.

15. The sampling method of claim 14, wherein in a test mode, the first delay time is set according to a test result and then the second delay time is set to be less than the first delay time and the third delay time is set to be greater than the first delay time, where a first difference between the first delay time and the second delay time is equal to a second difference between the first delay time and the third delay time; and the input data is sampled to obtain the output data in a normal operation mode.

16. The sampling method of claim 15, wherein if the first and second sampled values are identical to each other and the third sampled value is different from the first sampled value, then the first delay time, the second delay time, and the third delay time are decreased until the first, second, and third sampled values are all identical to each other; if the first and third sampled values are identical to each other and the second sampled value is different from the first sampled value, then the first delay time, the second delay time, and the third delay time are increased until the first, second, and third sampled values are all identical to each other; and if the second and third sampled values are both different from the first sampled value, then the first and second differences are decreased until one of the second and third sampled values is identical to the first sampled value.

17. The sampling method of claim 16, further comprising:
counting a disparity value when one of the first, second, and third sampled values is different from the other two sampled values;
wherein when the disparity value is greater than a threshold value, the first delay time, the second delay time, and the third delay time are increased or decreased or the first and second differences are decreased.

18. A sampling method for a memory, the sampling method comprising:
generating a data signal;
generating a data sampling signal;
delaying the data sampling signal by a first delay time to generate a first delayed signal;
delaying the data sampling signal by a second delay time to generate a second delayed signal;
utilizing the first delayed signal to sample the data signal so as to generate a first sampled value;
utilizing the second delayed signal to sample the data signal so as to generate a second sampled value;
performing a first comparing operation on the first sampled value and the second sampled value; and
adjusting at least the first delay time according to a result of the first comparing operation.

19. The sampling method of claim 18, further comprising:
delaying the data sampling signal by a third delay time to generate a third delayed signal;
utilizing the third delayed signal to sample the data signal so as to generate a third sampled value;
performing a second comparing operation on the first sampled value and the third sampled value; and
in addition to the result of the first comparing operation, referring to a result of the second comparing operation for adjusting the first delay time.

20. The sampling method of claim 18, further comprising:
performing a statistical counting operation on the result of the first comparing operation.
